(19) United States
(12) Patent Application Publication
(10) Pub. No.: US 2003/0227050 A1
(43) Pub. Date: Dec. 11, 2003

(54) Semiconductor device and manufacturing method thereof

(76) Inventor: Kenichi Yoshimochi, Kyoto (JP)

Correspondence Address: RABIN & CHAMPAGNE, PC, 1101 14TH STREET, NW, SUITE 500, WASHINGTON, DC, 20005, US

(21) Appl. No.: 10/424,977

(22) Filed: Apr. 29, 2003

(30) Foreign Application Priority Data
Apr. 30, 2002 (JP) 2002-128054

(51) Int. Cl. H01L 29/76; H01L 29/94

(52) U.S. Cl. 257/330

(57) ABSTRACT

A semiconductor device including a trench provided in a surface layer portion of a semiconductor substrate to allow a channel region to be exposed from an inner wall surface of the trench. The semiconductor device includes a gate insulation film formed on the inner wall surface of the trench, and a gate electrode placed inside the trench so as to oppose the inner wall surface of the trench with the gate insulation film in between. The gate electrode includes a low resistance layer chiefly made of a metal element.

### BACKGROUND OF THE INVENTION

1. Field of the Invention

The present invention relates to a semiconductor device having a trench structure and a manufacturing method thereof, and more particularly to a power MOS FET having a trench structure and a manufacturing method thereof.

2. Description of Related Art

A power MOS FET (Metal-Oxide-Semiconductor Field Effect Transistor) includes a type having a so-called trench structure, in which a trench or a hole is formed in a semiconductor substrate or a thin film formed on the surface of the semiconductor substrate. With this type of MOS FET, a channel region is placed along the inner surface of the trench in the depth direction of the trench. Hence, in comparison with a MOS FET of a so-called planar structure, in which the channel region is placed plane-wise along the surface of the semiconductor substrate, the above type of MOS FET enables miniaturization of elements and can thereby reduce power consumption.

A gate electrode made of polysilicon is embedded in the trench. Impurities are diffused into polysilicon forming the gate electrode, so that polysilicon is made into a p-type or n-type semiconductor to reduce a resistance value.

However, a resistance value, for example, the sheet resistance, of impurity-diffused polysilicon is still as high as 20 Ω/cm² approximately. A MOS FET provided with a gate electrode having such a high resistance value needs a long switching time for circuits. Hence, such a MOS FET is not suitably applied to a high-speed switching element or a high-speed operating circuit.

In addition, a large switching loss causes an increase of power consumption of the MOS FET.

### SUMMARY OF THE INVENTION

It is therefore an object of the invention to provide a semiconductor device operable at a high speed.

Another object of the invention is to provide a semiconductor device consuming less power.

A further object of the invention is to provide a manufacturing method of a semiconductor device operable at a high speed.

Still another object of the invention is to provide a manufacturing method of a semiconductor device consuming less power.

A semiconductor device of the invention includes a gate insulation film formed on an inner wall surface (particularly, an inner sidewall surface) of a trench provided in a surface layer portion of a semiconductor substrate to allow a channel region to be exposed through the inner wall surface, and a gate electrode placed inside the trench so as to oppose the inner wall surface of the trench with the gate insulation film in between and having a low resistance layer chiefly made of a metal element.

According to the invention, because the gate electrode includes the low resistance layer chiefly made of a metal element, a resistance value is low (for example, the sheet resistance is 0.3 Ω/cm² approximately) in comparison with a gate electrode made of polysilicon alone. It is preferable to adjust the sheet resistance of the gate electrode to be 5 Ω/cm² or below, and more preferably 1 Ω/cm² or below.

Consequently, a switching time of elements formed in the semiconductor device can be shortened, and the semiconductor device thus becomes operable at a high speed. For example, suppose that polysilicon is used for the gate electrode, then a time tₒₙ needed to switch ON the MOS FET is 15 to 20 nsec (nanoseconds) approximately, and a time t_{off} needed to switch OFF the MOS FET is 50 to 80 nsec. In contrast, by using a low resistance layer as the gate electrode, for example, tₒₙ can be shortened to 5 to 10 nsec and t_{off} can be shortened to 20 to 40 nsec.

Also, because a switching loss of the semiconductor device can be reduced, power consumption of the semiconductor device can be reduced. Hence, the semiconductor device can be suitably applied, for example, to a DC-to-DC converting circuit or a switching circuit.

The low resistance layer may include at least one of Al, Cu, W, Ti, Ni, Mo, Co, and Ag.

The low resistance layer made of the foregoing metal element(s) can reduce a resistance value of the gate electrode. The low resistance layer may be made of only one of the foregoing metal elements or alloy made of two or more of the foregoing metal elements (for example, Al—Cu alloy).

In a case where a fabrication sequence of the semiconductor device includes a step of subjecting the semiconductor substrate to annealing after the gate electrode is formed on the semiconductor substrate, it is preferable that the low resistance layer is made of metal having a high melting point, such as W and Mo, or alloy or a compound having a high solidus temperature. A melting point or a solidus temperature of the low resistance layer is preferably 1000° C. or above.

The low resistance layer may include an element (for example, Si or N) other than a metal element. For example, it may include Al—Si alloy or it may include TiN.

It is preferable that the semiconductor device further includes a polysilicon layer provided to lie between the low resistance layer and the gate insulation film.

When the low resistance layer is formed directly on the gate insulation film, a metal element contained in the low resistance layer may diffuse into the gate insulation film, which possibly deteriorates electrical insulation of the gate insulation film. However, by forming the polysilicon layer between the gate insulation film and the low resistance layer, it is possible to prevent diffusion of a metal element forming the low resistance layer into the gate insulation film.

Also, silicide of a metal element forming the low resistance layer may be formed in the vicinity of the boundary between the polysilicon and the low resistance layer. However, such silicide has so small a resistance value that the resistance of the gate electrode remains low.

A method of manufacturing a semiconductors device of the invention includes: a trench forming step of forming a trench in a surface layer portion of a semiconductor substrate, so that a channel region is exposed from an inner wall surface (in particular, an inner sidewall surface) of the trench; a step of forming a gate insulation film covering the inner wall surface of the trench; and a low resistance layer forming step of forming a low resistance layer chiefly made of a metal element inside the trench so as to oppose the inner wall surface of the trench with the gate insulation film in between.

According to the method of manufacturing a semiconductor device, the semiconductor device arranged as described above can be manufactured. The trench forming step may be performed through etching. The gate insulation film may be formed, for example, by giving rise to thermal oxidation in the vicinity of the inner wall surface of the trench.

The low resistance layer forming step may include a step of forming the low resistance layer chiefly made of a metal element through one of a sputtering method, a vapor deposition method, and a plating method.

The above and other objects, features, and advantages of the invention will become more apparent from the following description of embodiments with reference to the accompanying drawings.

### BRIEF DESCRIPTION OF THE DRAWINGS

FIG. 1 is a schematic cross section showing a structure of a MOS FET according to one embodiment of the invention; and

FIG. 2(a), FIG. 2(b), and FIG. 2(c) are schematic cross sections used to explain a manufacturing method of the MOS FET of FIG. 1.

### DESCRIPTION OF THE PREFERRED EMBODIMENTS

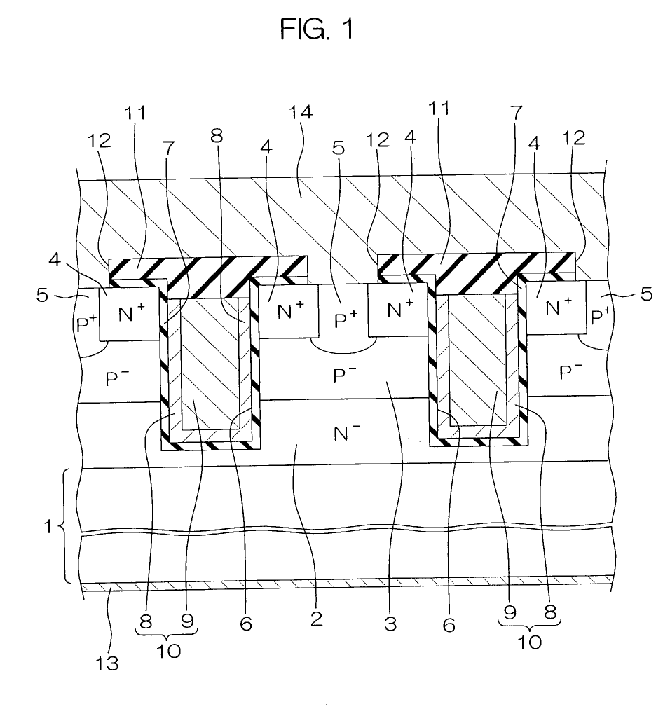

FIG. 1 is a schematic cross section showing a structure of a MOS FET according to one embodiment of the invention. An N⁻ epitaxial layer 2, a P⁻ channel layer 3, and an N⁺ source layer 4 are formed sequentially from bottom to top on a silicon substrate 1. A thickness of the P⁻ channel layer 3 is, for example, 0.5 μm approximately, and a thickness of the N⁺ source layer 4 is, for example, 0.5 μm approximately. A concentration of impurities of the P⁻ channel layer 3 is, for example, 2.0×10¹⁶ atoms/cm³ approximately. A concentration of impurities of the N⁺ source layer 4 is, for example, 1.0×10¹⁹ atoms/cm³ approximately.

P⁺ layers 5 are formed to divide the N⁺ source layer 4 at regular intervals. Also, a trench 6, which penetrates through the N⁺ source layer 4 and the P⁻ channel layer 3 and halfway through the N⁻ epitaxial layer 2 in the thickness direction, is formed between every two adjacent P⁺ layers 5. In other words, the P⁻ channel layer 3 is placed along the inner sidewall surface of each trench 6. A width of each trench 6 is, for example, 0.5 μm approximately, and a depth of the trench 6 is, for example, 1.5 μm approximately.

A gate oxide film 7 is formed on the inner surface of each trench 6 and atop the N⁺ source layer 4. A thickness of the gate oxide film 7 is, for example, 400 Å.

A gate electrode 10 is formed to fill in each trench 6 except for the top portion of the trench 6. Each gate electrode 10 extends in a direction perpendicular to the sheet plane in FIG. 1, and is drawn to the outside at a position outside of the drawing. The gate electrode 10 includes a polysilicon layer 8 placed in contact with the gate oxide film 7 and a low resistance layer 9 made of W (tungsten) and formed on the inner side of the polysilicon layer 8. A thickness of the polysilicon layer 8 is, for example, 2000 Å.

Silicide of metal forming the low resistance layer 9 is formed in the vicinity of the boundary between the polysilicon layer 8 and the low resistance layer 9. This reduces resistance of the polysilicon layer 8 either partly or entirely.

A silicon oxide layer 11 is formed on each gate electrode 10 and above the N⁺ source layer 4. A thickness of the silicon oxide layer 11 is, for example, 6000 Å approximately.

A contact hole 12, which penetrates through the gate oxide film 7 and the silicon oxide layer 11, is formed above each P⁺ layer S. An electrode film 14 made of Al or Al—Si alloy is formed over the silicon oxide layer 11 and inside the contact holes 12. A thickness of the electrode film 14 is, for example, 30 μm approximately.

A metal complex film 13 composed of a plurality of layered metal films including Au, Ti, Ni, Ag, etc. is formed on the silicon substrate 1 on the surface opposite to the N⁻ epitaxial layer 2. Of the entire metal complex film 13, a film made of Au is formed at a portion that comes in contact with the silicon substrate 1. The MOS FET is arranged in such a manner that it can be connected to a lead frame or the like on the surface on which the metal complex film 13 is formed.

In the MOS FET described above, most of the gate electrode 10 is made of the low resistance layer 9, and for this reason, the gate electrode 10 has low resistance (for example, the sheet resistance is 0.3 Ω/cm² approximately). This shortens a switching time for elements formed in the MOS FET, and the MOS FET thus becomes operable at a high speed.

Also, because the MOS FET can reduce a switching loss, it can reduce power consumption, and the MOS FET can be thereby suitably applied, for example, to a DC-to-DC converting circuit, a switching circuit, etc.

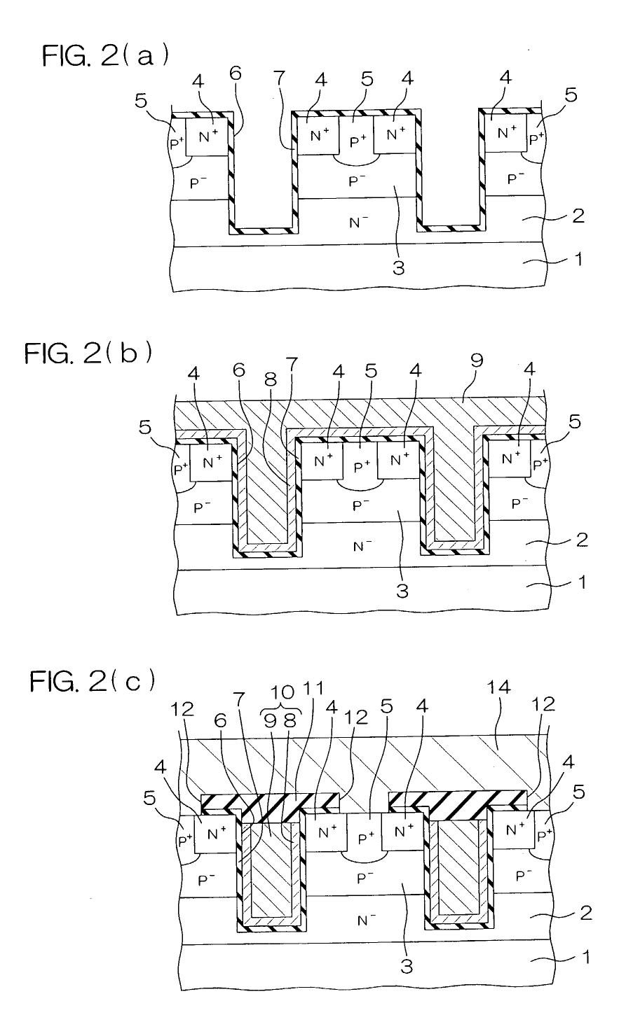

FIG. 2(a), FIG. 2(b), and FIG. 2(c) are schematic cross sections used to explain a manufacturing method of the MOS FET of FIG. 1.

The N⁻ epitaxial layer 2 is first formed on the silicon substrate 1. Then, impurities forming a p-type semiconductor are diffused into the N⁻ epitaxial layer 2 from the surface, and the top portion of the N epitaxial layer 2 is eventually made into the P⁻ channel layer 3. In this instance, a concentration of the impurities of the P⁻ channel layer 3 is adjusted to be 2.0×10¹⁶ atoms/cm³ approximately. A thickness of the P channel layer 3 is, for example, 1.0 μm approximately.

Then, the P⁺ layers 5 and the N⁺ source layer 4 are formed in the top portion of the P⁻ channel layer 3 through diffusion of impurities using resist having openings at predetermined positions as a mask. In this instance, a concentration of the impurities of the N⁺ source layer 4 is adjusted to be 1.0×10¹⁹ atoms/cm³ approximately. A thickness of the N⁺ source layer 4 is, for example, 0.5 μm approximately. In this case, a thickness of the P⁻ channel layer 3 is, for example, 0.5 μm.

Subsequently, the trenches 6, each of which penetrates through the N⁺ source layer 4 and the P⁻ channel layer 3 and halfway through the N⁻ epitaxial layer 2 in the thickness direction, are formed through etching using resist having openings at predetermined positions (between every two adjacent P⁺ layers 5) as a mask. A width of each trench 6 is, for example, 0.5 μm, and a depth of the trench 6 is, for example, 1.5 μm approximately.

Further, the silicon substrate 1 on which are formed the foregoing layers is heated to give rise to thermal oxidation in the vicinity of the surfaces of the N⁺ source layer 4 and the P⁺ layers 5 and in the vicinity of the inner surface of each trench 6. The gate oxide film 7 is thus obtained. A thickness of the gate oxide film 7 is, for example, 400 Å. FIG. 2(a) illustrates this state.

Subsequently, the polysilicon layer 8 is formed along the surface of the gate oxide film 7. The polysilicon layer 8 can be formed, for example, through the CVD (Chemical Vapor Deposition) method. A thickness of the polysilicon layer 8 is, for example, 2000 Å.

Further, the low resistance layer 9 is formed by depositing W (tungsten) atoms on the polysilicon layer 8, for example, through the sputtering method (FIG. 2(b)). The low resistance layer 9 is formed to fill in each trench 6, and a thickness of the low resistance layer 9 outside the trenches 6 is, for example, 20000 Å. In this instance, silicide of W (tungsten) forming the low resistance layer 9 is formed in the vicinity of the boundary between the polysilicon layer 8 and the low resistance layer 9.

The presence of the polysilicon layer 8 between the low resistance layer 9 and the gate oxide film 7 prevents diffusion of a metal element forming the low resistance layer 9 into the gate oxide film 7 when a film of the low resistance layer 9 is deposited or in the steps thereafter. This makes it possible to avoid an unwanted event that the electrical insulation of the gate oxide film 7 is deteriorated.

Subsequently, the metal complex film 13 (see FIG. 1) is formed on the silicon substrate 1 on the surface opposite to the N⁻ epitaxial layer 2 followed by annealing. In this instance, the low resistance layer 9 made of W will not melt owing to its high melting point (3400° C.).

Then, the polysilicon layer 8 and the low resistance layer 9 are removed through etching in a portion outside the trenches 6 and in a portion at the inside top of each trench 6. The gate oxide film 7 is exposed after the polysilicon layer 8 and the low resistance layer 9 are removed. Then, the silicon oxide layer 11 is formed to cover the exposed surfaces of the gate oxide film 7, the polysilicon layer 8 and the low resistance layer 9 through the CVD method. A thickness of the silicon oxide layer 11 is, for example, 6000 Å approximately.

Subsequently, the contact holes 12, each of which penetrates through the gate oxide film 7 and the silicon oxide layer 11, are formed through etching using resist having openings at predetermined positions as a mask, so that the P⁺ layers 5 and the surrounding N⁺ source layer 4 will be exposed. Then, the electrode film 14 made of Al or Al—Si alloy is formed to fill in the contact holes 12 through the sputtering method (See FIG. 2(c)). The electrode film 14 is deposited to have a thickness of, for example, 30 μm approximately.

In the manufacturing method described above, the gate and the channel are not positioned through self-alignment. Hence, there will be no inconvenience when polysilicon, to which the self-alignment technique is readily adapted, is not used for the gate electrode 10.

While the above description described the embodiment of the invention, the invention can be implemented in another embodiment. For example, a semiconductor device to which the invention is applicable is not limited to a MOS FET, and for example, a semiconductor device may be an IGBT (Insulated Gate Bipolar Transistor) instead.

The low resistance layer 9 is not necessarily made of W, and it may be made of one of Al (aluminum), Cu (copper), Ti (titanium), Ni (nickel), Mo (molybdenum), Co, (cobalt), and Ag (silver), and it may include alloy made of two or more of Al, Cu, W, Ti, Ni, Mo, Co, and Ag (for example, Al—Cu alloy).

Also, the low resistance layer 9 may include an element (for example, Si or N) other than a metal element, and for example, it may include Al—Si alloy, or TiN (titanium nitride).

In a case where the fabrication sequence of the MOS FET includes the annealing step described as above, it is preferable that the low resistance layer 9 is made of metal having a high melting point (for example, W and Mo) or alloy or a compound having a high solidus temperature. In this case, the low resistance layer 9 preferably has a melting point or a solidus temperature of 1000° C. or above.

The low resistance layer 9 may be formed through the vapor deposition method (for example, the CVD method) or the plating method instead of the sputtering method. A suitable film forming method can be selected from the foregoing methods depending on the kind of metal forming the low resistance layer 9.

Also, a PSG (Phospho Silicate Glass) film or a BPSG (Boro-Phospho Silicate Glass) film may be formed instated of the silicon oxide layer 11.

While the above description described embodiments of the invention in detail, it should be appreciated that these embodiments represent examples to provide clear understanding of the technical contents of the invention, and the invention is not limited to these examples. The sprit and the scope of the invention, therefore, are limited solely by the scope of the appended claims.

This application is based on Application No. 2002-128054 filed with the Japanese Patent Office on Apr. 30, 2002, the entire content of which is incorporated hereinto by reference.

What is claimed is:

1. A semiconductor device, comprising:
a gate insulation film formed on an inner wall surface of a trench provided in a surface layer portion of a semiconductor substrate to allow a channel region to be exposed through the inner wall surface; and
a gate electrode placed inside the trench so as to oppose the inner wall surface of the trench with the gate insulation film in between and having a low resistance layer chiefly made of a metal element.

2. The semiconductor device according to claim 1, wherein the low resistance layer includes at least one of Al, Cu, W, Ti, Ni, Mo, Co, and Ag.

3. The semiconductor device according to claim 1, wherein the low resistance layer includes Al-Si alloy.

4. The semiconductor device according to claim 1, wherein the gate electrode includes TiN.

5. The semiconductor device according to claim 1, further including a polysilicon layer provided to lie between the low resistance layer and the gate insulation film.

6. A method of manufacturing a semiconductor device, comprising:
a trench forming step of forming a trench in a surface layer portion of a semiconductor substrate, so that a channel region is exposed from an inner wall surface of the trench;
a step of forming a gate insulation film covering the inner wall surface of the trench; and
a low resistance layer forming step of forming a low resistance layer chiefly made of a metal element inside the trench so as to oppose the inner wall surface of the trench with the gate insulation film in between.

7. The method of manufacturing a semiconductor device according to claim 6, wherein the low resistance layer forming step includes a step of forming the low resistance layer chiefly made of a metal element through one of a sputtering method, a vapor deposition method, and a plating method.
